(19) United States
(12) Patent Application Publication
(10) Pub. No.: US 2026/0263968 A1
(43) Pub. Date: Sep. 10, 2026

(54) BUBBLE REMOVAL UNIT AND IMMERSION-COOLING ELECTRONIC DEVICE HAVING THE SAME

(71) Applicant: National Taiwan University, Taipei City (TW)

(72) Inventors: Ya-Yu CHIANG, Taipei City (TW); Ching-Wen LO, Taipei City (TW)

(21) Appl. No.: 19/349,154

(22) Filed: Oct. 3, 2025

Related U.S. Application Data
(60) Provisional application No. 63/768,043, filed on Mar. 6, 2025.

(30) Foreign Application Priority Data
Jul. 8, 2025 (TW) 114125838

(51) Int. Cl. B01D 19/00; H05K 7/20

(52) U.S. Cl. CPC B01D 19/0073; H05K 7/20236

(57) ABSTRACT

A bubble removal unit includes at least one coil that has a plurality of coil turns, that is adapted to be disposed above a surface of an electronic member at a set height in a removal direction for guiding a bubble to move in the removal direction into the at least one coil. One of the plurality of coil turns that is adapted to be closest to the surface of the electronic member has a diameter not greater than a first diameter of the bubble. For every two adjacent coil turns in the removal direction, a diameter of one of the adjacent coil turns adapted to be closer to the surface of the electronic member is not greater than a diameter of another one of the adjacent coil turns adapted to be farther from the surface of the electronic member for guiding the bubble to move therethrough.

### CROSS-REFERENCE TO RELATED APPLICATION

This application claims the benefit of U.S. Provisional Patent Application No. 63/768043, filed on Mar. 6, 2025, and claims priority to Taiwanese Invention Patent Application No. 114125838, filed on Jul. 8, 2025. The aforesaid applications are incorporated by reference herein in their entirety.

### FIELD

The disclosure relates to a cooling unit and a cooling device that has the cooling unit, and more particularly to a bubble removal unit and an immersion-cooling electronic device that has the bubble removal unit.

### BACKGROUND

A conventional cooling device (e.g., an electrolysis device or an immersion cooling device), which has a two-phase interface (e.g., a liquid-solid interface), produces a large amount of bubbles on a surface thereof during an electrolysis reaction process or a cooling process. The bubbles may linger on the surface after formation, and the longer the bubbles linger on the surface of the conventional cooling device, the worse the conventional cooling device performs (i.e., the worse a heat dissipation effect of the conventional cooling device). For example, under a circumstance where the conventional cooling device is an immersion cooling device, the conventional cooling device is filled with a non-conductive coolant. A power device that generates heat is immersed in the non-conductive coolant to lower a processing temperature thereof in order to prevent the heat from damaging the power device. During heat transfer between the non-conductive coolant and the power device, bubbles are generated on a surface of the power device that is in contact with the non-conductive coolant due to high temperature, and a portion of the bubbles may linger on the surface. The lingering bubbles may gather and form a vapor layer (that negatively affects the heat dissipation process of the power device) on the surface, which may result in heat accumulation.

A conventional method to alleviate the drawback of the conventional cooling device is to alter the hydrophilic property of the surface of the power device to facilitate detachment of the bubbles from the surface. However, the effect of the conventional method is limited; hence, designing a device that is more effective in detaching bubbles from the surface of the power device is an important issue for people in the field.

### SUMMARY

Therefore, an object of the disclosure is to provide a bubble removal unit that can alleviate at least one of the drawbacks of the prior art.

According to the disclosure, the bubble removal unit is adapted to be mounted to an electronic member of an immersion-cooling electronic device submerged in a liquid, and is adapted for guiding a bubble that is generated on a surface of the electronic member to move away from the surface. The bubble has a first diameter when attached to the surface and a second diameter after leaving the surface and before being in contact with the bubble removal unit. The first diameter is not greater than the second diameter. The bubble removal unit includes at least one coil that is adapted to be disposed above the surface of the electronic member at a set height in a removal direction with the set height being not greater than the second diameter of the bubble so as to smoothly guide the bubble to move in the removal direction into the at least one coil. Each of the at least one coil has a plurality of coil turns arranged in the removal direction. One of the plurality of coil turns that is adapted to be closest to the surface of the electronic member has a diameter not greater than the first diameter of the bubble. For every two adjacent coil turns in the removal direction, a diameter of one of the adjacent coil turns that is adapted to be closer to the surface of the electronic member is not greater than a diameter of another one of the adjacent coil turns that is adapted to be farther from the surface of the electronic member such that the plurality of coil turns are adapted for smoothly guiding the bubble to move therethrough.

Another aspect of the disclosure is to provide an immersion-cooling electronic device that includes a cooler unit, an electronic member, and the abovementioned bubble removal unit. The cooler unit includes a shell member defining a chamber, and a liquid retained in the chamber. The electronic member is disposed in the chamber, is submerged in the liquid, and has a surface in contact with the liquid. The bubble removal unit is mounted to the electronic member for guiding a bubble that is generated on the surface of the electronic member to move away from the surface.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating an embodiment of an immersion-cooling electronic device according to the disclosure.

FIG. 2 is a schematic view illustrating a coil (a) of the embodiment, a coil (b) of a variation of the embodiment, a coil (c) of another variation of the embodiment, and a coil (d) of yet another variation of the embodiment.

FIG. 3 is a schematic sectional view of the coil (c) in FIG. 2.

FIG. 4 illustrates two graphs, one of which shows relationships between heat flux and a degree of superheating of a first experimental group, a second experimental group and a reference group, and the other of which shows critical heat flux of each of the first experimental group, the second experimental group and the reference group.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

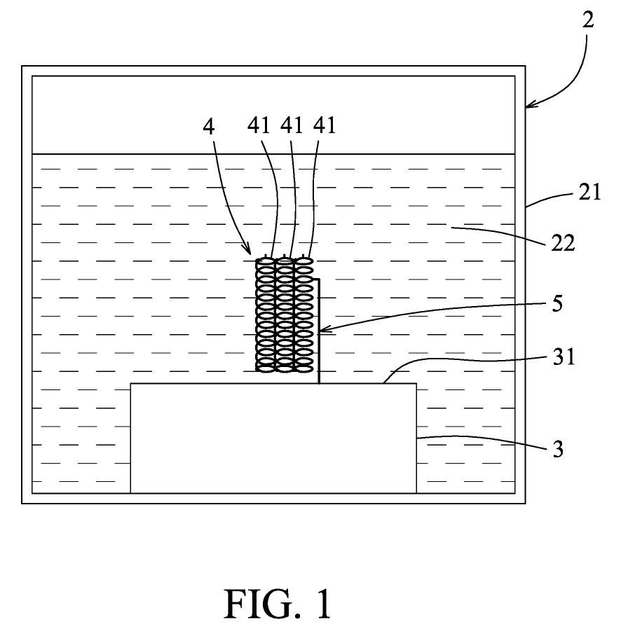

Referring to FIGS. 1 to 3, an embodiment of an immersion-cooling electronic device includes a cooler unit 2, an electronic member 3, a bubble removal unit 4, and a fixture unit 5.

The cooler unit 2 includes a shell member 21 defining a chamber, and a liquid 22 retained in the chamber.

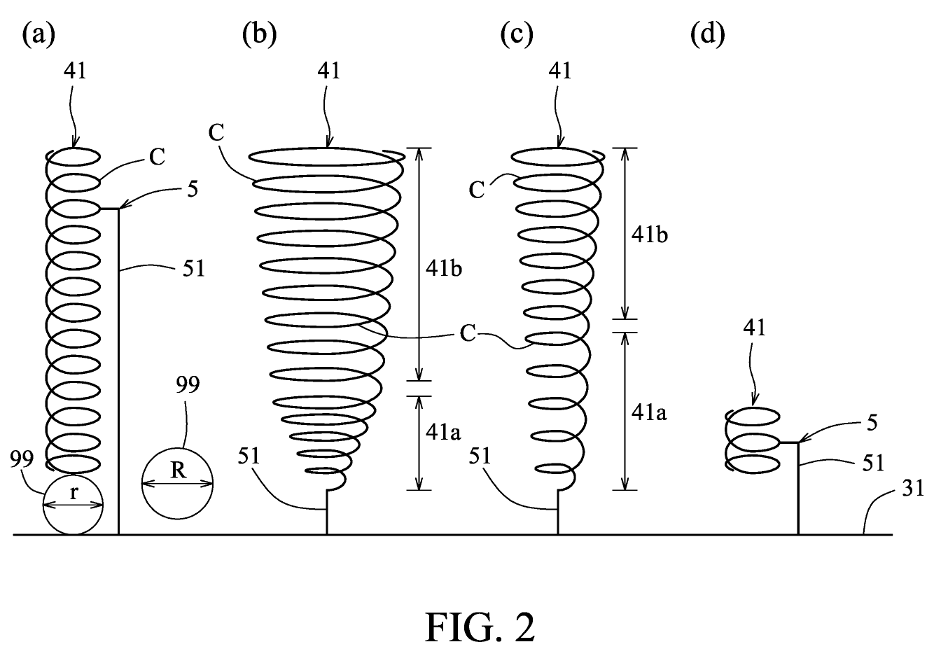

Referring to FIG. 2, the electronic member 3 is a power component that generates heat when being operated. The electronic member 3 is disposed in the chamber, is submerged in the liquid 22, and has a surface 31 that is in contact with the liquid 22. When the electronic member 3 generates heat, a bubble 99 is generated on the surface 31. The bubble 99 has a first diameter (r) when attached to the surface 31 and a second diameter (R) after leaving the surface 31 and before being in contact with the bubble removal unit 4. The first diameter (r) is not greater than the second diameter (R).

The fixture unit 5 fixedly interconnects the bubble removal unit 4 and the electronic member 3 for positioning the bubble removal unit 4 at a set height (h) relative to the surface 31 of the electronic member 3. The set height (h) is configured to be not greater than the second diameter (R) of the bubble 99. Specifically, the bubble removal unit 4 includes at least one coil 41 that is disposed above the surface 31 of the electronic member 3 at the set height (h) in a removal direction. In this embodiment, the at least one coil 41 includes three coils 41. Each of the coils 41 has a plurality of coil turns (C) arranged in the removal direction. For every two adjacent coil turns (C) in the removal direction, a diameter of one of the adjacent coil turns (C) that is closer to the surface 31 of the electronic member 3 is not greater than a diameter of another one of the adjacent coil turns (C) that is farther from the surface 31 of the electronic member 3. For each of the coils 41, one of the plurality of coil turns (C) that is closest to the surface 31 of the electronic member 3 has a diameter configured to be not greater than the first diameter (r) of the bubble 99.

In this embodiment, the coils 41 are connected to each other. In other embodiments, the coils 41 may be spaced apart from each other.

Each of the coils 41 has opposite ends that are opposite to each other in the removal direction, and a lateral side that is disposed between the opposite ends. The fixture unit 5 includes at least one fixture member 51 that interconnects the surface 31, and one of the opposite ends and the lateral side of one of the coils 41.

In this embodiment, the at least one fixture member 51 includes one fixture member 51. The fixture member 51 interconnects the surface 31 and the lateral side of the one of the coils 41. In other embodiments, the configuration of the coils 41, the fixture member 51, and the surface 31 may be different.

In a variation of the embodiment, each of the coils 41 is the coil (d) in FIG. 2. In this variation, each of the coils 41 has in the removal direction a length that is configured to be not greater than the second diameter (R) of the bubble 99. For each of the coils 41, the length in the removal direction shortens a period of time for which the bubble 99 lingers in the coil 41 so that another bubble 99 can enter the coil 41 and be detached from the surface 31.

In this embodiment, a pitch (G) between every two adjacent coil turns (C) in the removal direction is configured to range from 0.05 to 1.5 times the second diameter (R) of the bubble 99 such that the plurality of coil turns (C) are adapted to allow the bubble 99 to move therethrough in the removal direction. Specifically, for each of the coils 41, the bubble 99 is moved in the removal direction by a pushing force of the liquid 22 in the coil 41 and the buoyancy of the bubble 99. If a size of the pitch (G) is too small, the pushing force of the liquid 22 may be insufficient, and the bubble 99 may linger in the coil 41; if the size of the pitch (G) is too big, the bubble 99 may leave the coil 41 too early from between two adjacent ones of the plurality of coil turns (C).

In some embodiments, the pitch (G) is not smaller than a wire diameter (W) of each of the plurality of coil turns (C).

Since each of the coils 41 is disposed above the surface 31 of the electronic member 3 at the set height (h) in the removal direction, the bubble 99 can be smoothly guided to move in the removal direction into the coil 41. Since for every two adjacent coil turns (C) in the removal direction, the diameter of the one of the adjacent coil turns (C) that is closer to the surface 31 of the electronic member 3 is not greater than the diameter of the another one of the adjacent coil turns (C) that is farther from the surface 31 of the electronic member 3, the plurality of coil turns (C) can smoothly guide the bubble 99 to move therethrough. The configuration of the coil 41 guides the bubble 99 into the coil 41 when the bubble 99 is formed on the surface 31, thereby lowering the chance of the bubble 99 forming a vapor layer, and the chance of the bubble 99 merging with another bubble lingering on the surface 31 and forming a large vapor layer with the another bubble.

In this embodiment, each of the coils 41 is the coil (a) in FIG. 2; the diameters of the coil turns (C) are the same, and the pitch (G) between every two adjacent coil turns (C) in the removal direction is the same. In some embodiments, each of the coils 41 is one of the coil (b) and the coil (c) in FIG. 2, and each of the coils 41 has a first segment 41a that is proximate to the surface 31 of the electronic member 3, and that includes a portion of the plurality of coil turns (C), and a second segment 41b that is distal from the surface 31 of the electronic member 3, and that includes a remaining portion of the plurality of coil turns (C).

For example, in a variation of the first embodiment, each of the coils 41 is the coil (b) in FIG. 2, and the diameters of the coil turns (C) increase in the removal direction. Specifically, the diameters of the plurality of coil turns (C) in the first segment 41a increase at a first rate of change in the removal direction, and the diameters of the plurality of coil turns (C) in the second segment 41b increase at a second rate of change in the removal direction. The first rate of change is greater than the second rate of change. In other embodiments, the first rate of change may be smaller than the second rate of change.

Furthermore, in another variation of the first embodiment, each of the coils 41 is the coil (c) in FIG. 2. A pitch (G) between every two adjacent coil turns (C) in the first segment 41a in the removal direction is different from a pitch (G) between every two adjacent coil turns (C) in the second segment 41b in the removal direction. In this variation, the diameters of the coils 41 increase in the removal direction, and the pitch (G) between every two adjacent coil turns (C) in the first segment 41a in the removal direction is bigger than the pitch (G) between every two adjacent coil turns (C) in the second segment 41b in the removal direction. In other embodiments, the pitch (G) between every two adjacent coil turns (C) in the first segment 41a in the removal direction may be smaller than a pitch (G) between every two adjacent coil turns (C) in the second segment 41b in the removal direction.

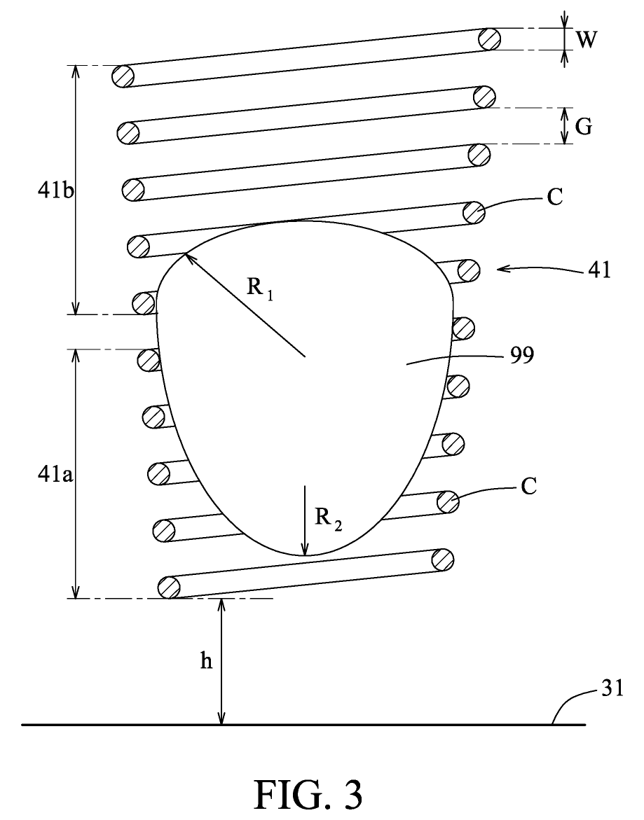

By virtue of the first rate of change being different from the second rate of change, and the pitch (G) in the first segment 41a being different from that in the second segment 41b, a pressure generated by the coil turns (C) in the first segment 41a and the coil turns (C) in the second segment 41b for pushing the bubble 99 in the removal direction is increased, thereby speeding up a detachment process of the bubble 99. Moreover, referring to FIG. 3, since the diameters of the coil turns (C) increase in the removal direction, when the bubble 99 enters the coil 41, the bubble 99 has a conical shape, and has an upper portion having an upper diameter (R1), and a lower portion having a lower diameter (R2) that is smaller than the upper diameter (R1). Since the lower diameter (R2) is smaller than the upper diameter (R1), there is a pressure discrepancy between the upper portion and the lower portion of the bubble 99, which results in a force that drives the bubble 99 to move in the removal direction, thereby increasing speed of the bubble 99 moving in the removal direction. Thus, the bubble 99 enters the coil 41 faster and efficiency of the detachment process is increased.

Furthermore, it should be noted that, the bubble removal unit 4 is adapted to be used in an environment with a two-phase (liquid-solid) interface for guiding bubbles that are in contact with both the liquid and solid phases to move away from the solid phase. For example, in this embodiment, the bubble removal unit 4 is adapted for guiding the bubble 99, which is in contact with the liquid 22 and the surface 31 of the electronic member 3, to move away from the surface 31. In another embodiment, the electronic member 3 is omitted, and the bubble removal unit 4 is mounted to an electrolysis device (not shown) having two electrodes (not shown), and is adapted for removing bubbles generated on the electrodes during an electrolysis process of the electrolysis device to prevent the bubbles from building up on the electrodes and decreasing a reaction area of the electrodes.

The following is a heat dissipation experiment and the analysis thereof, comparing the heat dissipation of the bubble removal unit 4 of a first experimental group, the heat dissipation of the bubble removal unit 4 of a second experimental group, and the heat dissipation of a reference group. In the heat dissipation experiment, a copper plate acts as the surface 31, and the bubble removal units 4 of the first experimental group and the second experimental group are fixed above the copper plate. The experiment is conducted by having the bubble removal unit 4 remove bubbles from the copper plate when the electronic device 3 is in use, and measuring data related to heat dissipation.

The bubble removal unit 4 of the first experimental group includes seven coils 41 that are connected to each other. Each of the coils 41 is the coil (a) in FIG. 2. The diameters of the coil turns (C) are the same, and the pitch (G) between every two adjacent coil turns (C) in the removal direction is the same. The length of each coil 41 in the removal direction is 1cm.

The bubble removal unit 4 of the second experimental group is similar to that of the first experimental group, but includes three coils 41.

The reference group does not have any coils 41. The analysis result is as follows.

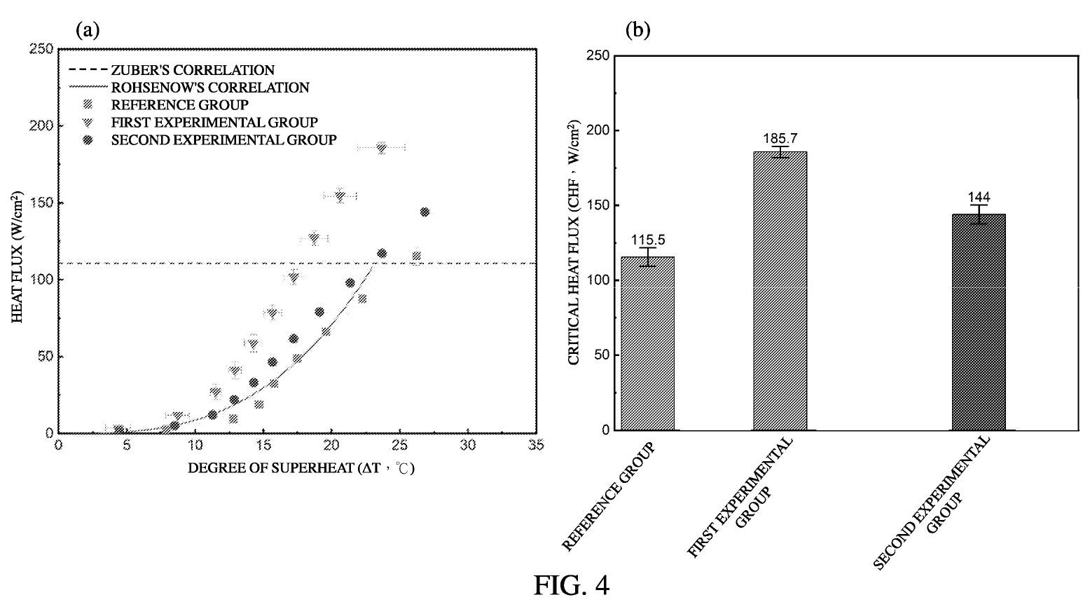

Referring to FIG. 4, the graph (a) shows a relationship between a degree of superheat and heat flux. In graph (a), Zuber’s correlation is presented by a dashed line, and Rohsenow’s correlation is presented by a solid line. The degree of superheat represents a temperature discrepancy between a temperature of the copper plate and a boiling point of the liquid 22. The results of the first experimental group and the second experimental group show that, under the same degree of superheat, the greater the number of the coils 41, the higher the heat flux, and the better the heat dissipation. In other words, when the surface 31 is under the same heating condition, the bubble detaching efficiency increases with the number of the coils 41, thereby achieving greater heat dissipation. Moreover, referring to the graph (b), a growth rate of critical heat flux (CHF) of the first experimental group relative to the reference group, which is around 61%, is greater than a growth rate of critical heat flux of second experimental group relative to the reference group, which is around 25%. The critical heat flux represents the greatest heat transfer effect of the surface 31 when it is in a nucleate boiling state (i.e., when the surface 31 is in a state where a large quantity of bubbles are formed on the surface 31). If the degree of superheat is over the temperature discrepancy (the critical heat flux occurs due to the temperature discrepancy), the nucleate boiling state transitions into a film boiling state, in which a vapor layer is formed on the surface 31, which lowers thermal conductivity, and may cause the electronic device 3 to be damaged. The results shown in the graph (b) illustrate that, when there are more coils 41, the bubbles 99 can be effectively detached from the surface 31, thereby achieving greater heat transferring effects. Furthermore, through the results shown in both the graph (a) and graph (b), an appropriate working temperature range can be found and applied in order to prevent film boiling, and to further prevent thermal runaway.

In conclusion, since each of the coils 41 is disposed above the surface 31 of the electronic member 3 at the set height (h) in the removal direction, and since dimensions of each of the coils 41 are designed in accordance to the first diameter (r) and the second diameter (R) of the bubble 99, the bubble 99 can be effectively guided to move away from the surface 31, thereby preventing the bubble 99 from lingering on the surface 31 and preventing a vapor layer from forming on the surface 31. Hence, the objective of the disclosure is achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A bubble removal unit that is adapted to be mounted to an electronic member of an immersion-cooling electronic device submerged in a liquid, and that is adapted for guiding a bubble generated on a surface of the electronic member to move away from the surface, the bubble having a first diameter when attached to the surface and a second diameter after leaving the surface and before being in contact with said bubble removal unit, the first diameter being not greater than the second diameter, said bubble removal unit comprising:
at least one coil that is adapted to be disposed above the surface of the electronic member at a set height in a removal direction with the set height being not greater than the second diameter of the bubble so as to smoothly guide the bubble to move in the removal direction into said at least one coil;
wherein each of said at least one coil has a plurality of coil turns arranged in the removal direction, one of said plurality of coil turns that is adapted to be closest to the surface of the electronic member having a diameter not greater than the first diameter of the bubble; and
wherein for every two adjacent coil turns in the removal direction, a diameter of one of said adjacent coil turns that is adapted to be closer to the surface of the electronic member is not greater than a diameter of another one of said adjacent coil turns that is adapted to be farther from the surface of the electronic member such that said plurality of coil turns are adapted for smoothly guiding the bubble to move therethrough.

2. The bubble removal unit as claimed in claim 1, wherein for each of said at least one coil, a pitch between every two adjacent coil turns in the removal direction is configured to range from 0.05 to 1.5 times the second diameter of the bubble such that said plurality of coil turns are adapted to allow the bubble to move therethrough in the removal direction.

3. The bubble removal unit as claimed in claim 1, wherein each of said at least one coil has in the removal direction a length that is configured to be not greater than the second diameter of the bubble to shorten a period of time for which the bubble lingers in said each of said at least one coil.

4. The bubble removal unit as claimed in claim 1, wherein for each of said at least one coil, a pitch between every two adjacent coil turns in the removal direction is not smaller than a wire diameter of each of said plurality of coil turns.

5. The bubble removal unit as claimed in claim 1, wherein:
each of said at least one coil has a first segment that is adapted to be proximate to the surface of the electronic member, and that includes a portion of said plurality of coil turns, and a second segment that is adapted to be distal from the surface of the electronic member, and that includes a remaining portion of said plurality of coil turns; and
a pitch between every two adjacent coil turns in said first segment in the removal direction is different from a pitch between every two adjacent coil turns in said second segment in the removal direction.

6. The bubble removal unit as claimed in claim 5, wherein for each of said at least one coil:
diameters of said plurality of coil turns in said first segment increase at a first rate of change in the removal direction; and
diameters of said plurality of coil turns in said second segment increase at a second rate of change in the removal direction, said first rate of change being different from said second rate of change.

7. The bubble removal unit as claimed in claim 1, wherein:
each of said at least one coil has a first segment that is adapted to be proximate to the surface of the electronic member, and that includes a portion of said plurality of coil turns, and a second segment that is adapted to be distal from the surface of the electronic member, and that includes a remaining portion of said plurality of coil turns;
diameters of said plurality of coil turns in said first segment increase at a first rate of change in the removal direction; and
diameters of said plurality of coil turns in said second segment increase at a second rate of change in the removal direction, said first rate of change being different from said second rate of change.

8. The bubble removal unit as claimed in claim 1, wherein said at least one coil includes a plurality of coils that are connected to each other.

9. An immersion-cooling electronic device comprising:
a cooler unit that includes a shell member defining a chamber, and a liquid retained in said chamber;
an electronic member that is disposed in said chamber, that is submerged in said liquid, and that has a surface in contact with said liquid; and
the bubble removal unit as claimed in claim 1, the bubble removal unit being mounted to said electronic member for guiding a bubble that is generated on said surface of said electronic member to move away from said surface.

10. The immersion-cooling electronic device as claimed in claim 9, wherein for each of said at least one coil, a pitch between every two adjacent coil turns in the removal direction is configured to range from 0.05 to 1.5 times the second diameter of the bubble such that said plurality of coil turns are adapted to allow the bubble to move therethrough in the removal direction.

11. The immersion-cooling electronic device as claimed in claim 9, wherein each of said at least one coil has in the removal direction a length that is configured to be not greater than the second diameter of the bubble to shorten a period of time for which the bubble lingers in said each of said at least one coil.

12. The immersion-cooling electronic device as claimed in claim 9, wherein for each of said at least one coil, a pitch between every two adjacent coil turns in the removal direction is not smaller than a wire diameter of each of said plurality of coil turns.

13. The immersion-cooling electronic device as claimed in claim 9, wherein:
each of said at least one coil has a first segment that is proximate to the surface of the electronic member, and that includes a portion of said plurality of coil turns, and a second segment that is distal from the surface of the electronic member, and that includes a remaining portion of said plurality of coil turns; and
a pitch between every two adjacent coil turns in said first segment in the removal direction is different from a pitch between every two adjacent coil turns in said second segment in the removal direction.

14. The bubble removal unit as claimed in claim 13, wherein for each of said at least one coil:
diameters of said plurality of coil turns in said first segment increase at a first rate of change in the removal direction; and
diameters of said plurality of coil turns in said second segment increase at a second rate of change in the removal direction, said first rate of change being different from said second rate of change.

15. The immersion-cooling electronic device as claimed in claim 9, wherein:
each of said at least one coil has a first segment that is proximate to the surface of the electronic member, and that includes a portion of said plurality of coil turns, and a second segment that is distal from the surface of the electronic member, and that includes a remaining portion of said plurality of coil turns;
diameters of said plurality of coil turns in said first segment increase at a first rate of change in the removal direction; and
diameters of said plurality of coil turns in said second segment increase at a second rate of change in the removal direction, said first rate of change being different from said second rate of change.

16. The immersion-cooling electronic device as claimed in claim 9, wherein said at least one coil includes a plurality of coils that are connected to each other.

17. The immersion-cooling electronic device as claimed in claim 9, further comprising a fixture unit fixedly interconnecting said bubble removal unit and said electronic member for positioning said bubble removal unit at said set height relative to said surface of said electronic member.

18. The immersion-cooling electronic device as claimed in claim 17, wherein:
each of said at least one coil has opposite ends that are opposite to each other in the removal direction, and a lateral side that is disposed between said opposite ends; and
said fixture unit includes at least one fixture member that interconnects said surface, and one of said opposite ends and said lateral side of said at least one coil.
